(19) United States
(12) Patent Application Publication
(10) Pub. No.: US 2025/0291256 A1
(43) Pub. Date: Sep. 18, 2025

(54) MIRROR ARRANGEMENT FOR ABSORBING RADIATION, AND LITHOGRAPHY SYSTEM

(71) Applicant: Carl Zeiss SMT GmbH, Oberkochen (DE)

(72) Inventor: Herman BIEG, Huettlingen (DE)

(21) Appl. No.: 19/226,322

(22) Filed: Jun. 3, 2025

Related U.S. Application Data
(63) Continuation of application No. PCT/EP2023/084042, filed on Dec. 4, 2023.

(30) Foreign Application Priority Data
Dec. 6, 2022 (DE) 10 2022 213 143.6

(51) Int. Cl. G03F 7/00; G02B 26/08

(52) U.S. Cl. CPC G03F 7/702; G02B 26/0833; G03F 7/70833; G03F 7/70891; G03F 7/70958

(57) ABSTRACT

A mirror arrangement, such as for a lithography system, comprises: a plurality of mirror elements for reflecting radiation; a plurality of carrier elements, which each carry one of the mirror elements; and a mount arrangement having insert openings formed in each case to accommodate a respective one of the carrier elements, with the plurality of carrier elements, which each carry one of the mirror elements, being accommodated in the insert openings of the mount arrangement. For absorbing radiation, at least one of the insert openings does not accommodate a carrier element and/or, for absorbing radiation, at least one of the insert openings accommodates a dummy carrier element which does not carry a mirror element.

### CROSS-REFERENCE TO RELATED APPLICATIONS

The present application is a continuation of, and claims benefit under 35 USC 120 to, international application No. PCT/EP2023/084042, filed Dec. 4, 2023, which claims benefit under 35 USC 119 of German Application No. 10 2022 213 143.6, filed Dec. 6, 2022. The entire disclosure of each of these applications is incorporated by reference herein.

### FIELD

The disclosure relates to a mirror arrangement, such as for a lithography system, comprising: a plurality of mirror elements for reflecting radiation, a plurality of carrier elements, which each carry one of the mirror elements, and a mount arrangement having insert openings formed in each case to accommodate a respective one of the carrier elements, with the plurality of carrier elements, which each carry one of the mirror elements, being accommodated in the insert openings of the mount arrangement. The disclosure also relates to a lithography system having at least one such mirror arrangement.

The lithography system can be a lithography apparatus for exposing a wafer or some other optical arrangement used for lithography, for example an inspection system, for example for inspecting masks, wafers, (mirror) elements or the like that are used in lithography. The lithography system can be embodied for use in EUV lithography, for example in the form of an EUV lithography apparatus which is used to produce semiconductor components and operated with short wavelength radiation, so-called EUV radiation, at an operating wavelength between approximately 5 nanometers (nm) and approximately 30 nm.

### BACKGROUND

Heat arises in lithography systems, specifically in EUV lithography apparatuses, inter alia by the absorption of EUV radiation, the heating of optical elements for example in the form of mirrors, due to frictional losses during the movement of actuators, etc. The heat arising during the operation of a lithography system can be dissipated by virtue of the components of the lithography system being cooled.

By way of example, the components to be cooled can be mirror elements in the form of micromirror arrays, especially in the form of micro-electromechanical mirror modules (“MEMS mirror modules”). A MEMS mirror module has a plurality of micromirrors in a grid arrangement, the micromirrors typically being actuatable or tiltable about at least one axis, such as about two axes. The micromirrors are typically very small components in each case (size of the respective mirror surface approximately 1 square millimeter (mm²) for example) and are controlled or actuated with the aid of logic elements and micromechanical structures in chip format. The actuation of the micromirrors of a respective mirror module is often accompanied by the release of heat which can be difficult to dissipate on account of the small dimensions of the micromirrors or on account of the mount thereof.

DE 10 2013 205 214 B4 describes micromechanical or microelectromechanical equipment for a projection exposure apparatus, comprising at least one micromechanical or microelectromechanical element and a temperature-control device comprising a gas supply mechanism and a gas aspiration mechanism. The at least one micromechanical or microelectromechanical element is encapsulated in a housing which has a gas supply line and a gas removal line and at least one window for the working light of the projection exposure apparatus. The equipment can be a multi-mirror arrangement having a multiplicity of electromechanical micromirrors.

DE 10 2014 219 770 A1 describes a mirror arrangement comprising: at least one mirror element carrying a mirror surface provided for reflecting electromagnetic radiation, at least one carrier element comprising a head portion provided for accommodating at least one mirror element and a seat portion, and a mount arrangement for accommodating the at least one carrier element. At least one insert opening is formed in the mount arrangement and the seat portion of the carrier element is dipped into the insert opening. A channel device for guiding a heat carrying medium is formed in the mount arrangement in the region of the seat portion. A local channel system (heat pipe), which can be formed in the carrier element, is embodied to assist the heat transfer from the region of the head portion to the region of the seat portion, in conjunction with a phase change of a heat carrying medium introduced into this local channel system of the carrier element. For example, the mirror elements can each form a mirror array.

The mirror arrangement described above can be used for example in an illumination system of a lithography apparatus serving to illuminate an object field in which a reticle is arranged. Such an illumination system can be designed such that only two mirror arrangements having a plurality of micromirror elements are present. In this case, a first mirror arrangement in the beam path can be designed as field-forming element in the form of a specular reflector and a second mirror arrangement in the beam path can serve to image the specular reflector into the exit pupil of the illumination system, for example as described in DE 10317667 A1. The first and the second mirror arrangement can be designed as facet mirrors.

Compared to illumination systems having at least three mirror arrangements, the illumination system described in DE 10317667 A1 can provide improved transmission and hence a higher productivity of the lithography apparatus. For the generation of certain illumination settings, inter alia in the case of such an illumination system, it is in general not helpful for the system performance if light reflected by the mirror elements in the first mirror arrangement reaches the object field of the illumination system.

In principle, a beam dump supplied with unwanted radiation can be used to absorb light or radiation. For this purpose, DE 10 2015 210 041 A1 proposes the use of at least one lamella arrangement having at least one reflective lamella. The lamella arrangement is arranged such that it reflects light, which is incident on the lamella arrangement at least intermittently during operation of the projection exposure apparatus and does not belong to the used light tube, toward at least one beam dump.

### SUMMARY

The disclosure seeks to provide a mirror arrangement which absorbs unwanted radiation and, in the process, influences the optical performance of the mirror arrangement as little as possible. The disclosure also seeks to provide a lithography system, such as a lithography apparatus, having at least one such mirror arrangement.

According to a first aspect, the disclosure provides a mirror arrangement, such as for a lithograph system, comprising: a plurality of mirror elements for reflecting radiation, a plurality of carrier elements, which each carry one of the mirror elements, and a mount arrangement having insert openings formed in each case to accommodate a respective one of the carrier elements, with the plurality of carrier elements, which each carry one of the mirror elements, being accommodated in the insert openings of the mount arrangement. For absorbing incident radiation, at least one of the insert openings does not accommodate a carrier element (and no dummy carrier element either) and/or wherein, for absorbing incident radiation, at least one of the insert openings accommodates a dummy carrier element which does not carry a mirror element.

The number of insert openings in the mirror arrangement according to the disclosure is greater than the number of carrier elements with mirror elements attached thereto, which are inserted into the insert openings. The at least one insert opening not accommodating a carrier element can serve as a beam dump, and/or the at least one dummy carrier element not carrying a mirror element can serve as a beam dump. The dummy carrier element not carrying a mirror element typically can have a seat portion which dips into the insert opening and is formed identically or similarly to a seat portion of a carrier element which carries a mirror element. The number of beam dumps, which is to say the number of insert openings without carrier elements or number of dummy carrier elements which do not carry a mirror element, can be specified practically as desired within the scope of the production of the mirror arrangement, depending on how much power is intended to be dissipated. Additionally, the number of beam dumps may optionally be varied after the production of the mirror arrangement since the carrier elements are typically detachably connected to the mount arrangement and hence individual carrier elements can be removed or carrier elements carrying a mirror element can be replaced with dummy carrier elements which do not carry any mirror elements.

As described further above, a dedicated component in the form of a beam dump thermally decoupled from the mirror arrangement may serve, in principle, for the absorption of radiation. However, absorbing radiation via a separate component serving as a beam dump is not possible in every case since the radiation to be absorbed usually is steered to the beam dump. The case where the mirror arrangement according to the disclosure is the second mirror arrangement of an illumination system, which is intended to absorb some of the radiation emanating from a first mirror arrangement of the illumination system so that the radiation does not reach the reticle or the object field, can mean that the mirror elements in the first mirror arrangement, which are typically in the form of micromirrors, can only be tilted through a comparatively small angle upon actuation. This can lead to the unwanted radiation emanating from the first mirror arrangement generally not being able to be steered to a separate beam dump thermally decoupled from the second mirror arrangement since such a beam dump cannot be reached as a result of the restricted switching range of the mirror elements in the first mirror arrangement. To steer the unwanted radiation to the beam dump, the switching range or the angle at which the mirror elements in the first mirror arrangement can be tilted would have to be increased. This can be problematic from a manufacturing point of view.

In order to be able to absorb unwanted radiation despite the limited switching range of the mirror elements in the first mirror arrangement, it can be desirable to place a beam dump on the mount arrangement of the second mirror arrangement, in the vicinity of the mirror elements in the second mirror arrangement. However, such an arrangement can harbour the risk of the mount arrangement heating at the site of the beam dump, and hence thermoelastically deforming. This can impair the positioning accuracy of the mirror elements in the second mirror arrangement, at which the incident radiation is intended to be reflected; as a consequence, the mirror elements might no longer accurately strike the envisaged position on the reticle or drift away thermally.

The mirror arrangement according to the disclosure can allow incident radiation to be absorbed without the optical performance of the mirror arrangement being influenced significantly in the process. The absorbed radiation can be effectively absorbed and dissipated at the insert opening or at the dummy carrier element accommodated in the insert opening, with the result that significant heating of the mount arrangement and hence a thermal drift behaviour of the mirror elements can be prevented.

To cool the insert opening serving as a beam dump or to cool the dummy carrier element serving as a beam dump, use can be made of known concepts for cooling mirror elements, for example as described in DE 10 2014 219 770 A1 cited at the outset, the latter being incorporated in the content of this application in its entirety by reference. In the case of the mirror arrangement described above, components in the mirror arrangement already present can be used for the realization of the beam dump. Hence, it is not necessary to newly develop or manufacture a beam dump and an associated cooling concept for the beam dump. For example, one and the same cooling device or one and the same cooling system can be used for cooling the mirror elements and the insert opening serving as a beam dump and/or the dummy carrier element serving as a beam dump. In this way, it is possible to keep the heating of the mount arrangement very low in the region of the beam dump (of the same order of magnitude as if a mirror element were integrated there). Moreover, it is possible to realize an efficient cooling system and hence a small thermal deformation of the mount arrangement, whereby a thermal drift behaviour of the mirror elements is prevented.

In an embodiment, the mirror arrangement comprises at least one channel device serving to guide a coolant and formed in the mount arrangement in the region of at least one insert opening not accommodating a carrier element and/or in the region of a seat portion of at least one dummy carrier element. With the aid of the channel device, heat can be efficiently dissipated from the insert opening serving as beam dump and/or from the dummy carrier element. The temperature of the coolant guided through the channel device can be adapted such that it substantially corresponds to the target temperature of the mirror arrangement. For example, the channel device can be embodied in the manner described in DE 10 2014 219 770 A1 for the purpose of cooling a respective mirror element. As described therein, a respective carrier element typically has a seat portion which dips into the insert opening. However, in contrast to the carrier element described therein, no mirror element is attached to a head portion of the dummy carrier element serving as a beam dump. Instead, the head portion can serve as a beam dump for absorbing radiation.

In an embodiment, an inner wall of at least one insert opening is formed by a socket element incorporated in the mount arrangement, optionally with the channel device for guiding the coolant being formed, at least in portions, by a cutout extending in the region of the outer side of the socket element.

As described in DE 10 2014 219 770 A1, the channel device for guiding the coolant can be provided by virtue of being formed, at least in portions, by a cutout extending in the region of the outer side of the socket element which for example is in the form of a hollow cone. In an alternative or in addition, it is possible to also form groove or channel structures provided to guide the coolant in the main body forming the mount arrangement. It is also possible for the coolant to be guided via a channel device formed directly in the mount arrangement or via a channel system which communicates with the channel device provided on the part of the socket element. It is also possible that the channel device for guiding the coolant or the channel system extends solely in the main body of the mount arrangement, without a socket element being used. Dispensing with the socket element is possible, for example, if the mount arrangement or its main body is produced by additive manufacturing, for example using 3-D printing methods. The channel system formed in the mount arrangement can be designed so that parallel cooling of the surrounding regions of a plurality of insert openings is brought about thereby. For example, the channel system can be used to cool the surroundings of all insert openings, which is to say both the insert openings in which mirror elements are inserted and insert openings in which no carrier element is inserted or in which a dummy carrier element is accommodated.

In an embodiment, at least one insert opening not accommodating a carrier element has on its inner wall a radiation absorbing coating and/or a radiation absorbing surface structure. Should no carrier element be accommodated in the insert opening, the radiation intended not to be reflected by the mirror arrangement is substantially incident on the inner wall of the insert opening, where it should be absorbed as efficiently as possible. In principle, practically any material absorbs EUV radiation, i.e., an absorbent coating or an absorbent surface structure on the inner side of the insert opening is not necessarily present for the absorption of EUV radiation. However, the radiation incident on the mirror arrangement or on the beam dump can also be radiation with longer wavelengths than the EUV wavelength range, for example with wavelengths in the EUV, UV, VIS or IR wavelength range. For example, the radiation generated by an EUV light source may contain radiation components which have wavelengths outside of the EUV wavelength range and which should not propagate within the lithography system.

Radiation in these wavelength ranges can be effectively absorbed by the provision of a radiation absorbing coating and/or a radiation absorbing surface structure, for example in the form of suitably formed microstructures. As described further above, the inner wall of the insert opening may be formed by a socket element which is provided with the absorbent coating or the absorbent surface structure on its inner side. However, this is not mandatory, which is to say the inner wall of the insert opening can also be formed directly on the mount arrangement.

In an embodiment, at least one insert opening not accommodating a carrier element is gas-tightly sealed, optionally at an end distant from the mirror elements. As described in DE 10 2014 219 770 A1, a respective carrier element is typically inserted in sealing (gas-tight) fashion into the socket element in order to gas-tightly seal the insert opening. In this way, a vacuum can be applied to the side of the mirror arrangement on which the mirror elements are arranged, without this leading to a gas inflow from the rearward region of the mount arrangement, in which typically no vacuum is applied, via the joining region of the carrier elements. Gas-tight closure of the insert opening can be desirable for the same reason if no carrier element is accommodated in the insert opening. For example, this can be achieved by the insertion of a seal, for example in the form of a plug, in the aforementioned socket element, or by virtue of the socket element having a pot-shaped embodiment and a base which gas-tightly seals the insert opening.

In general, it is desirable for the insert opening to be gas-tightly sealed at its side distant from the mirror elements and not at its side at the mirror elements in order to be able to use the largest possible area of the inner wall of the insert opening as a beam dump. For example, radiation components that, upon first incidence on the inner wall, were not absorbed but undesirably reflected can also be reflected multiple times in the insert opening and be incident on the inner wall again, in order to be absorbed in full.

In an embodiment, at least one dummy carrier element has a head region protruding beyond the insert opening, the head region optionally protruding further beyond the insert opening than the head regions of the carrier elements which carry a mirror element. In general, the mirror elements have a block-like or cuboid-like embodiment. Especially if the mirror elements are MEMS mirror modules (see below), they may have a non-negligible thickness since the control logic is also incorporated in the mirror elements, in addition to the tiltable micromirrors. Thus, to efficiently absorb the radiation via the dummy carrier element, it can be desirable for the head region to protrude further beyond the insert opening in the case of the dummy carrier element than in the case of those carrier elements which carry a mirror element. For example, the head region or its end face can protrude so far beyond the insert opening that it terminates approximately flush with the top side of the mirror elements (in a non-tilted position).

In an embodiment, the dummy carrier element has an absorbent coating and/or an absorbent surface structure on a head region protruding beyond the insert opening, such as on an end face of the head region. As described further above, this can be desirable for absorbing incident radiation at longer wavelengths than the EUV wavelength range. Should a dummy carrier element be accommodated in the insert opening, the dummy carrier element typically has a head region which protrudes beyond the insert opening and on which a majority of the radiation intended to be absorbed by the dummy carrier element is incident. An absorbent coating and/or an absorbent surface structure can be provided on the protruding head region, such as its end face. However, this is not mandatory.

In an embodiment, the at least one dummy carrier element has a solid embodiment, at least in the head region, for example throughout. An effective heat dissipation can be ensured by the solid embodiment of the dummy carrier element. By contrast, the carrier elements carrying a mirror element generally have a through channel for guiding connection and control lines through the carrier element, in order thus to connect the actuators included in the mirror elements to an electronic actuation system.

In a development, a closed channel system with an introduced coolant is formed in the dummy carrier element, with the coolant, optionally in conjunction with a phase change, bringing about a heat transfer from the head region to the seat portion of the dummy carrier element. The coolant in the closed channel system, possibly present in the form of water for example, can absorb heat without changing its phase. A closed channel system with an introduced coolant, in the case of which there is, in conjunction with a phase change, a heat transfer from the head region to the seat portion of the dummy carrier element, can for example be based on the principle of a heat pipe.

In an alternative development, the dummy carrier element has a channel system for guiding the coolant, the channel system comprising an inlet for the coolant and an outlet for the coolant. In contrast to the embodiment described further above, the channel system is not closed in this case, which is to say the dummy carrier element is cooled directly. In this way, the heat path from the heat source (the surface on which the radiation is incident) to the coolant can be reduced or kept as short as possible. Typically, the channel system of the dummy carrier element is designed to supply the coolant to the head region of the dummy carrier element and to discharge the coolant from the head region of the dummy carrier element.

In a development of this embodiment, the mirror arrangement is designed to fluid-tightly connect the inlet and the outlet of the channel system to the channel device of the mount arrangement or to a channel device of a heatsink arranged adjacent to the mount arrangement.

In the first case described further above, the mount arrangement can have a channel device which comprises a supply opening for supplying the coolant to the inlet and a discharge opening for discharging the coolant from the outlet of the channel system of the dummy carrier element. For example, sealing between the dummy carrier element and the channel device of the mount arrangement can be implemented with the aid of radial seals if the inlet and the outlet of the channel system are formed on the seat portion of the carrier element, or with the aid of an axial sealing arrangement if the inlet and the outlet are arranged on the head region of the carrier element, with a lateral offset from the insert opening.

In the second case described further above, the inlet and the outlet can be directly connected to a channel device of a heatsink arranged adjacently to the mount arrangement and are typically not fluid-tightly connected to the channel device of the mount arrangement. The fluid-tight connection of the inlet and the outlet of the dummy carrier element to the channel device of the heatsink can be implemented with the aid of a sealing arrangement. For example, the sealing arrangement can be designed as an axial or radial seal.

In an alternative, the inlet and the outlet of the dummy carrier element can be connected via lines, for example via tubes, to external cooling equipment or an external cooling circuit, in order to enable direct cooling.

As described in DE 10 2014 219 770 A1, the (dummy) carrier element can be geometrically adapted so that it provides a cross section which is sufficient for the heat transfer and as large as possible, at least in the seat portion which dips into the mount arrangement. A material with good thermal conductivity and moderate thermal expansion, optionally as little thermal expansion as possible can be selected for the carrier element. For example, copper, silicon, SiC, molybdenum alloys, tungsten alloys or else stainless steel come into question as the material. The seat portion of the carrier element and the inner wall of the insert opening can have a conical or cone-like form. However, this is not mandatory and the seat portion of the carrier element and the inner wall of the insert opening can also have a cylindrical form, for example.

For example, the coolant can be water, an aqueous mixture, glycol, a gas or a gas mixture or liquid CO₂, wherein the phase transition from the liquid to the gaseous phase can be advantageously used in the latter, for example in the heat pipe described further above.

In an embodiment, the mirror elements are in the form of MEMS mirror modules. A MEMS mirror module has a plurality of microelectromechanically actuatable micromirrors, generally arranged in a grid arrangement (array). As described further above, the respective micromirrors are individually actuatable and can typically be tilted about at least one axis, generally about two axes. The number of micromirrors in a MEMS mirror module may vary. By way of example, 24×24 or 25×25 micromirrors, for example, can be arranged in a grid arrangement. A respective MEMS mirror module typically also comprises logic elements and micromechanical structures in chip format, in order to control or actuate the micromirrors.

In an embodiment, the plurality of mirror elements are arranged in a grid arrangement, with at least one insert opening not accommodating a carrier element and/or at least one insert opening accommodating a dummy carrier element being arranged at a lateral edge of the grid arrangement or between the mirror elements of the grid arrangement, for example in the center of the grid arrangement. As described further above, it can be desirable for the insert opening serving as a beam dump or the carrier element serving as a beam dump to be arranged as close as possible to the mirror elements in the mirror arrangement because this means that the switching range of the mirror elements of a further mirror arrangement disposed upstream in the beam path need not be increased in order to steer the radiation reflected there to the respective beam dump of the mirror arrangement according to the disclosure. A beam dump at the lateral edge of the grid arrangement is situated at an outermost position of a respective row and/or column of the grid arrangement. A beam dump at the edge of the grid arrangement is also understood as meaning a beam dump placed immediately adjacently to a beam dump arranged at the outermost position. In an alternative or in addition to the arrangement of the beam dump(s) at the lateral edge of the grid arrangement, it is also possible to place the beam dump(s) in a manner distributed between the mirror elements of the grid arrangement, which is to say not at the edge of the grid arrangement but for example in the centre or middle of the grid arrangement.

In the cooling concepts described further above, it is possible to replace a respective carrier element which carries a mirror element or which serves as a beam dump, without the cooling circuit needing to be opened or interrupted in the process.

A fixing portion of a respective carrier element may serve to fix the (dummy) carrier elements to the mount arrangement, and a holding force securing the carrier element in the mount arrangement is introduced into the carrier element via the fixing portion. For example, the fixing portion can be in the form of a threaded portion, seated on which there is a nut which, in the tightened state, generates the holding force. The holding force generated by the nut can be conducted into the mount arrangement by the inclusion of a spring, for example. A press-out mechanism allowing the carrier element to be pressed out of the mount arrangement “from below” can also be positioned in the region of the fixing portion.

A further aspect of the disclosure relates to a lithography system, such as a lithography apparatus, comprising: at least one mirror arrangement as described further above, with the mirror arrangement optionally being arranged in an illumination system of the lithography apparatus. The lithography system can be a lithography apparatus for exposing a wafer or some other optical arrangement for lithography, for example an inspection system, for example for inspecting masks, wafers or the like that are used in lithography. The lithography system may be an EUV lithography system, which is designed for used radiation at wavelengths in the EUV wavelength range between 5 nm and 30 nm.

The illumination system may have exactly two mirror arrangements, of which the first mirror arrangement in the beam path forms a specular reflector as described in DE 10317667 A1 cited at the outset, which is incorporated in the content of this application in its entirety by reference. The illumination system can also be embodied differently and for example have three or more mirror arrangements. For example, the mirror arrangements may be in the form of facet mirrors.

In an embodiment, the lithography system comprises a further mirror arrangement having a plurality of further mirror elements, with the further mirror arrangement being arranged in the illumination system in the beam path upstream of the mirror arrangement and the plurality of further mirror elements being designed to radiate radiation to be absorbed at the at least one insert opening not accommodating a carrier element and/or at the at least one insert opening accommodating a dummy carrier element. Moreover, the further mirror arrangement is designed to radiate radiation to be reflected at the mirror elements of the mirror arrangement in order to radiate this at the object field or reticle. For example, the further mirror elements of the further mirror arrangement can be MEMS mirror modules.

As described further above, it can be desirable in this case for the mirror elements and the insert openings or dummy carrier elements serving as a beam dump to be arranged as adjacently to one another as possible so that the further mirror elements in the further mirror arrangement need not be tilted too far in order to guide the radiation to be absorbed to the insert openings serving as a beam dump or to the dummy carrier elements of the mirror arrangement according to the disclosure.

Further features and aspects of the disclosure will be apparent from the description of working examples of the disclosure that follows, with reference to the figures of the drawing, which show certain details of the disclosure, and from the claims. The individual features can be implemented individually in their own right or collectively in any combination in a variant of the disclosure.

### BRIEF DESCRIPTION OF THE DRAWINGS

Exemplary embodiments are illustrated in the schematic drawing and are explained in the following description. In the figures:

FIG. 1 shows a schematic meridional section through a projection exposure apparatus for EUV projection lithography, having an illumination system which has two facet mirrors;

FIG. 2 shows a perspective illustration of a mirror arrangement in the form of the second facet mirror of the illumination system of FIG. 1;

FIG. 3 shows a schematic illustration of a plan view of the mirror elements of the facet mirror of FIG. 2, which are arranged in a grid arrangement, with a plurality of beam dumps for absorbing radiation being arranged at the lateral edge and in the center of the grid arrangement;

FIG. 4A shows a schematic illustration of the mirror arrangement of FIG. 3 with a beam dump in the form of an insert opening which does not accommodate a carrier element;

FIG. 4B shows a schematic sectional illustration of the mirror arrangement of FIG. 3 with a beam dump in the form of a dummy carrier element which does not accommodate a mirror element;

FIG. 4C shows a schematic sectional illustration analogous to FIG. 4A, with a mount arrangement produced by 3-D printing; and

FIGS. 5A-5B show schematic illustrations of a dummy carrier element with a channel system introduced therein, the channel system having an inlet and an outlet for a coolant.

### DETAILED DESCRIPTION

In the description of the drawings that follows, identical reference signs are used for components that are the same or have the same function.

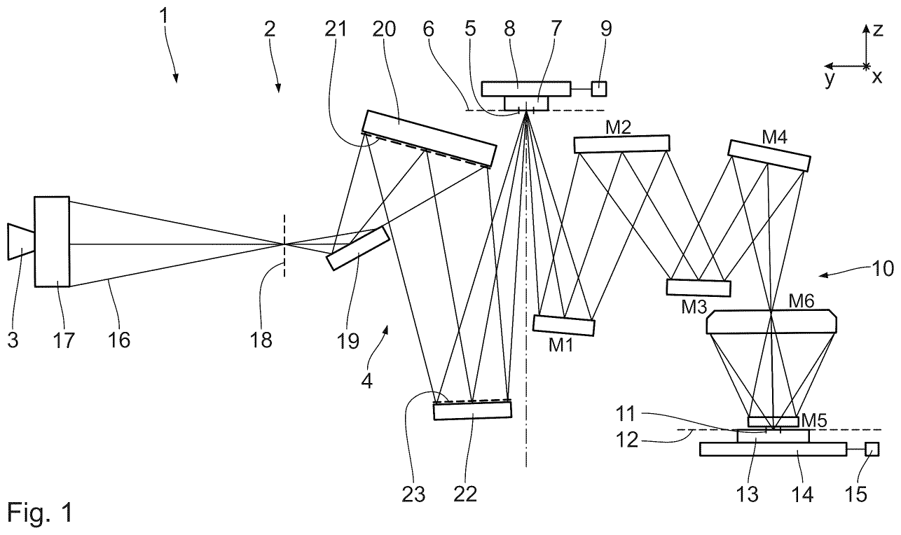

Certain parts of an optical arrangement for EUV lithography in the form of a microlithographic projection exposure apparatus 1 (EUV lithography apparatus) are described by way of example below with reference to FIG. 1. The description of the basic structure of the projection exposure apparatus 1 and of the parts thereof should not be regarded here as having a limiting effect.

An embodiment of an illumination system 2 of the projection exposure apparatus 1 has, in addition to a light or radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable, for example in a scanning direction, by way of a reticle displacement drive 9.

For explanatory purposes, a Cartesian xyz-coordinate system is depicted in FIG. 1. The x-direction runs perpendicularly into the plane of the drawing. The y-direction runs horizontally, and the z-direction runs vertically. The scanning direction runs in the y-direction in FIG. 1. The z-direction runs perpendicular to the object plane 6.

The projection exposure apparatus 1 comprises a projection system 10. The projection system 10 is used to image the object field 5 into an image field 11 in an image plane 12. A structure on the reticle 7 is imaged onto a light-sensitive layer of a wafer 13 arranged in the region of the image field 11 in the image plane 12. The wafer 13 is held by a wafer holder 14. The wafer holder 14 is displaceable, for example in the y-direction, by way of a wafer displacement drive 15. The displacement of the reticle 7 on the one hand by way of the reticle displacement drive 9 and of the wafer 13 on the other hand by way of the wafer displacement drive 15 may be synchronized with one another.

The radiation source 3 is an EUV radiation source. The radiation source 3 emits EUV radiation 16, which is also referred to below as used radiation, illumination radiation or illumination light. For example, the used radiation has a wavelength in the range between 5 nm and 30 nm. The radiation source 3 may be a plasma source, for example an LPP source (Laser Produced Plasma) or a GDPP source (Gas Discharge Produced Plasma). It may also be a synchrotron-based radiation source. The radiation source 3 may be a free electron laser (FEL).

The illumination radiation 16 emanating from the radiation source 3 is focused by a collector mirror 17. The collector mirror 17 may be a collector mirror with one or more ellipsoidal and/or hyperboloidal reflection surfaces. The illumination radiation 16 may be incident on the at least one reflection surface of the collector mirror 17 with grazing incidence (GI), which is to say at angles of incidence of greater than 45°, or with normal incidence (NI), which is to say at angles of incidence of less than 45°. The collector mirror 17 may be structured and/or coated, firstly to optimize its reflectivity for the used radiation and secondly to suppress extraneous light.

The illumination radiation 16 propagates through an intermediate focus in an intermediate focal plane 18 downstream of the collector mirror 17. The intermediate focal plane 18 may constitute a separation between a radiation source module, comprising the radiation source 3 and the collector mirror 17, and the illumination optical unit 4.

The illumination optical unit 4 comprises a deflection mirror 19 and, arranged downstream thereof in the beam path, a first facet mirror 20. The deflection mirror 19 can be a plane deflection mirror or, alternatively, a mirror with a beam-influencing effect that goes beyond the purely deflecting effect. In an alternative or in addition, the deflection mirror 19 may be in the form of a spectral filter that separates a used light wavelength of the illumination radiation 16 from extraneous light at a wavelength deviating therefrom. The first facet mirror 20 comprises a multiplicity of individual first facets 21, which are also referred to below as field facets. FIG. 1 depicts only some of the facets 21 by way of example. In the beam path of the illumination optical unit 4, a second facet mirror 22 is arranged downstream of the first facet mirror 20. The second facet mirror 22 comprises a plurality of second facets 23.

The illumination optical unit 4 thus forms a double-faceted system. This basic principle is also referred to as a fly's eye integrator. The individual first facets 21 are imaged into the object field 5 with the aid of the second facet mirror 22. The second facet mirror 22 is the last beam-shaping mirror or else indeed the last mirror for the illumination radiation 16 in the beam path upstream of the object field 5.

The projection system 10 comprises a plurality of mirrors Mi, which are consecutively numbered in accordance with their arrangement in the beam path of the projection exposure apparatus 1.

In the example depicted in FIG. 1, the projection system 10 comprises six mirrors M1 to M6. Alternatives with four, eight, ten, twelve or any other number of mirrors Mi are likewise possible. The penultimate mirror M5 and the last mirror M6 each have a through opening for the illumination radiation 16. The projection system 10 is a doubly obscured optical unit. The projection optical unit 10 has an image-side numerical aperture that is greater than 0.4 or 0.5 and may also be greater than 0.6, and may, for example, be 0.7 or 0.75.

Just like the mirrors of the illumination optical unit 4, the mirrors Mi can have a highly reflective coating for the illumination radiation 16.

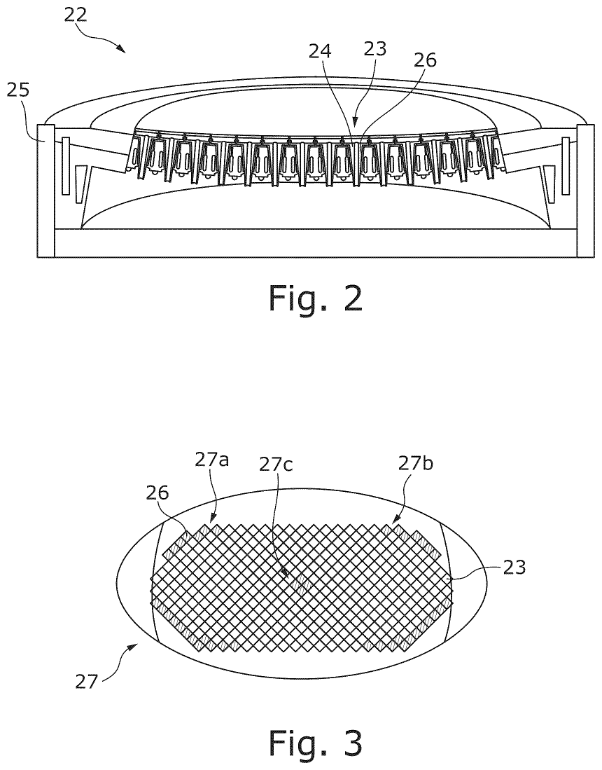

FIG. 2 shows the mirror arrangement in the form of the second facet mirror 22 of the illumination system 2 of FIG. 1 in a partial section. The mirror arrangement 22 has a plurality of mirror elements 23 which are arranged in close proximity, form a concave surface and are aligned with respect to an optical centre. Each mirror element 23 serves to reflect electromagnetic radiation, more precisely EUV radiation 16 which is reflected from the facets 21 of the first facet mirror 20 in the illumination system 2 to the mirror arrangement 22 in the form of the second facet mirror. In the example shown, the mirror elements 23 are in the form of MEMS mirror modules. A respective MEMS mirror module has a number of micromirrors which are arranged in a grid (e.g., with 25×25 micromirrors) and which can be actuated, more precisely tilted, on an individual basis. A respective mirror element 23 in the form of a MEMS mirror module has logic elements and micromechanical structures in chip format for this purpose.

The mirror arrangement 22 shown in FIG. 2 also comprises a plurality of carrier elements 24, which each carry one of the mirror elements 23. The mirror arrangement 22 also has a mount arrangement 25 which comprises conically formed insert openings 26 designed to accommodate a respective one of the conically shaped carrier elements 24, which each carry a respective mirror element 23. The mount arrangement 25 has a multi-part structure and has a plurality of frame shells put together in layered fashion. Regarding details of the structure of the mirror arrangement 22, of how the carrier elements 24 are fastened to the mount arrangement 25 and the structure of the mount arrangement 25, reference is made to DE 10 2014 219 770 A1.

FIG. 3 shows the mirror arrangement 22 of FIG. 2 in a plan view of the mirror elements 23, more precisely the reflective surfaces or end faces thereof, which have a square geometry in the example shown. It is understood that the mirror elements 23 may also have a different geometry. As likewise evident from FIG. 3, the mirror elements 23 are arranged in a grid arrangement 27 having a plurality of rows and columns. Grid positions illustrated by dashed lines in FIG. 3 which likewise each have an insert opening 26 but no mirror element 23 arranged thereon can be identified at the lateral edge 27a of the grid arrangement 27. The grid positions at the edge of the grid arrangement 27 shown in FIG. 3 serve as beam dumps for absorbing EUV radiation 16 which is reflected by the facets 21 in the first facet mirror 20 to the mirror arrangement in the form of the second facet mirror 22 but should not reach the reticle 7. Catching or absorbing radiation 16 which is reflected by certain facets 21 in the first facet mirror 20 at a respective angle position provided to this end is advantageous in the case of certain illumination settings or operating states of the illumination system 2.

The provision of beam dumps at the lateral edge 27a of the grid arrangement 27 of the mirror elements 23 is advantageous since the facets 21 in the first facet mirror 20 can be actuated (tilted as a rule) but the tilt angle settable during the actuation is comparatively small. As a rule, it is therefore not possible to steer the unwanted radiation 16 emanating from the facets 21 in the first facet mirror 20 to a beam dump arranged next to the second facet mirror 22. However, the switching range of the facets 21 in the first facet mirror 20 is sufficient to steer the unwanted radiation to the lateral left edge 27a and right edge 27b of the grid arrangement 27 of the mirror elements 23, in order to absorb this radiation 16 incident there. In an alternative or in addition to the arrangement of the beam dump(s) at the lateral edge 27a, 27b of the grid arrangement 27, it is also possible to place the beam dump(s) in distributed fashion between the mirror elements 23 of the grid arrangement, for example at the centre 27c of the grid arrangement 27, as depicted in FIG. 3.

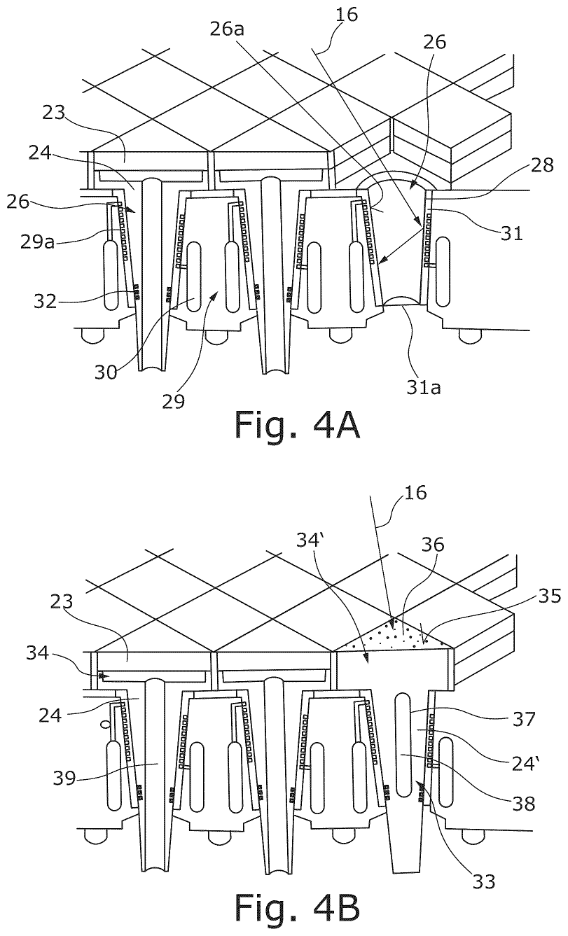

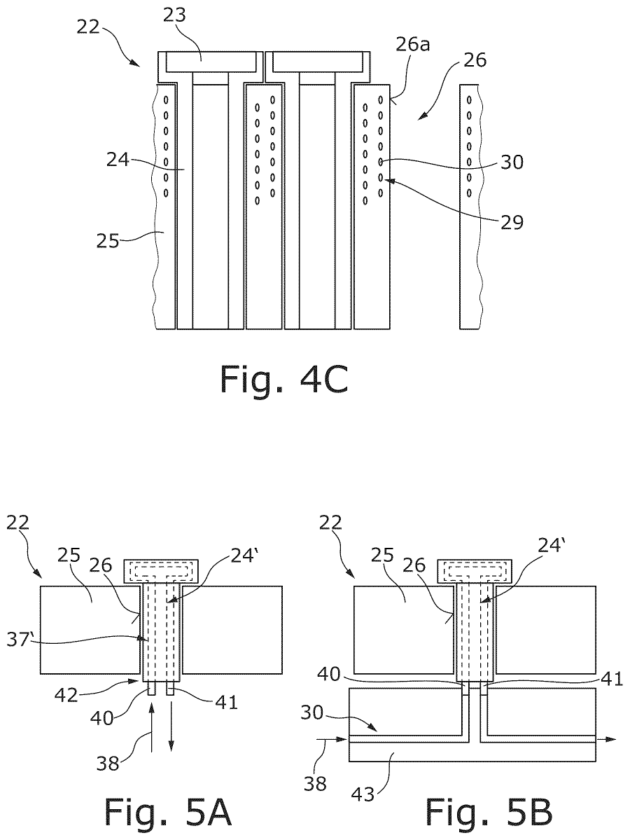

In order to avoid the case where the mount arrangement 25 deforms during the absorption of the radiation 16 and the mirror elements 23 no longer deflect the incident radiation 16 to the desired positions on the reticle 7, it is desirable to efficiently cool the mount arrangement 25 at the grid positions that serve to absorb the radiation 16. Two options for effective cooling or for the dissipation of heat are described below in conjunction with FIG. 4A and FIG. 4B.

FIG. 4A shows a beam dump in the form of an insert opening 26 not accommodating a carrier element 24, and two adjacent insert openings 26 which each accommodate a carrier element 24 carrying a mirror element 23. It is evident from FIG. 4A that the radiation 16 to be absorbed enters the insert opening 26 at a side of the mount arrangement 25 facing the mirror elements 23 and is reflected multiple times at an inner wall 26a of the insert opening 26, with a significant portion of the radiation 16 to be absorbed being absorbed in each case at the inner wall 26a. The inner wall 26a of the insert opening 26 need not necessarily have a conical geometry as depicted in FIG. 4A; instead, it could also have a cylindrical or any other geometry.

In the example shown, the inner wall 26a of the insert opening 26 is provided with an absorbent coating 28 for the incident radiation 16 to be absorbed. In an alternative or in addition, the inner wall 26a of the insert opening 26 may have an absorbent surface structure. In the example shown, the absorbent coating 28 is designed to absorb radiation at wavelengths longer than 30 nm generated by the light source 3, for example radiation in the VUV, UV, VIS or IR wavelength range. Even without an absorbent coating 28 or surface structure, the material of the inner wall 26a of the insert opening 26 absorbs a significant proportion of the incident radiation 16 at wavelengths in the EUV wavelength range.

According to Kirchhoff's law of thermal radiation, the following applies to the emissivity ε (the uptake of the incident radiation by the beam dump on account of absorption in the present case), the reflection δ and the transmission τ (in each case in %): ε+δ+τ=1. All three parameters are dependent on the wavelength and the angle of incidence of the incident radiation 16, with this dependence being neglected to simplify things in the consideration below. The effective emissivity ε_{eff} of the beam dump (corresponding to the effective absorption of the beam dump) for the incident radiation 16 depends not only on the emissivity ε of the beam dump in the case of a respective reflection at the inner wall 26a but also on the number of reflections n at the inner wall 26a. In the present case, the effective emissivity ε_{eff} of the beam dump should be as close as possible to 1 so that the radiation 16 which falls into the beam dump is converted as completely as possible into heat, which can be removed with the aid of a cooling mechanism.

The effective emissivity ε_{eff} of the beam dump can be estimated in accordance with the following formula: ε_{eff}=1−(1−ε)ⁿ. In this formula, the influence of the angle of incidence was neglected and the assumption was made that τ=0 applies to the transmission. For example, if an emissivity ε of the beam dump for the entirety of the incident radiation 16 (averaged over radiation in the EUV wavelength range and in other wavelength ranges) is assumed to be approx. 35% in the case of a reflection at the inner wall 26a and if n=3 reflections are assumed, then the following arises for the effective emissivity: ε_{eff}=72.5%. As described further above, the emissivity ε was in this case averaged over all wavelengths of the incident radiation 16. The emissivity ε and hence also the effective emissivity ε_{eff} of the beam dump for the incident radiation 16 in the EUV wavelength range is significantly higher than the value calculated here.

In order to effectively dissipate the absorbed radiation 16, the mount arrangement 25 has a channel device 29 in the form of a channel system serving to guide a coolant 30, cooling water in the example shown here. Alternatively, other coolants could also be used, for example aqueous mixtures, glycol, gases or gas mixtures or (liquid) CO₂. In the example shown in FIG. 4A, the inner wall 26a of the insert opening 26 is formed by a socket element 31 which is incorporated in the mount arrangement 25. In the example shown, the channel device 29 for guiding the coolant 30 is formed, in portions, by a cutout 29a which extends in the region of the outer side of the socket element 31. Regarding details of the design of the channel device 29 and the interaction with the socket element 31, reference is made to DE 10 2014 219 770 A1.

At its end distant from the mirror elements 23, the conically formed socket element 31 has a base 31a which gas-tightly seals the insert opening 26. This allows a vacuum to be applied to the side of the mirror arrangement 22 on which the mirror elements 23 are arranged, without in the process a gas flow from the rearward region of the mount arrangement 25 being able to reach the front side of the mirror arrangement 22 through the insert opening 26. As an alternative to the solution depicted in FIG. 4A, use can be made of a seal, for example in the style of a plug or the like, to gas-tightly seal the insert opening 26. The carrier elements 24 are also inserted into the respective socket elements 31 so as to seal the latter. Sealing is realized by seals in the form of O-rings 32, which are inserted in corresponding annular grooves in the carrier elements 24.

FIG. 4B shows an illustration analogous to FIG. 4A, in which the beam dump is realized by a dummy carrier element 24′ which, in contrast to the two other carrier elements 24 depicted in FIG. 4B, does not carry a mirror element 23. The dummy carrier element 24′ which serves as a beam dump has a seat portion 33 which projects into the insert opening 26 and a head region 34′ which protrudes beyond the insert opening 26 in the direction of the mirror elements 23. The head region 34′ protrudes further beyond the insert opening 26 than the head regions 34 of the adjacent carrier elements 24, which each carry a mirror element 23. The further protruding head region 34′ has an end face 35 which terminates flush with the end faces or the reflective surfaces of the adjacent mirror elements 23. This and the provision of an absorbent surface structure 36 on the end face 35 of the head region 34′ allows the radiation 16 incident on the head region 34′ of the dummy carrier element 24′ to be absorbed effectively. The absorption of the incident radiation 16 at the end face 35 of the head region 34′ should be greater than 70%.

To effectively dissipate the absorbed heat from the head region 34′ of the dummy carrier element 24′, a closed channel system 37 with an introduced coolant 38 is formed in the dummy carrier element 24′, more precisely in the seat portion 33, the coolant, in combination with a phase change, bringing about a heat transfer from the head region 34′ to the seat portion 33 of the dummy carrier element 24′ (a so-called heat pipe). By way of example, the coolant 38 can be CO₂. Alternatively, the coolant 38 in the closed channel system 37 might not change its phase. As evident from FIG. 4B, the closed channel system 37 is restricted to the seat portion 33 of the dummy carrier element 24′; i.e., the head region 34′ of the dummy carrier element 24′ has a solid embodiment, but this is not mandatory. By way of contrast, the carrier elements 24 carrying a mirror element 23 each have a through channel 39 for guiding connection and control lines through the carrier element 24, in order thus to connect the actuators included in the mirror elements to an electronic actuation system.

Unlike what is depicted in FIG. 4B, the dummy carrier element 24′ may also have a solid embodiment throughout, which is to say it has no cavities. In both cases, the dummy carrier element 24′ can be cooled in the manner described in the context of FIG. 4A, which is to say with the aid of the channel device 29 which is designed to guide the coolant 30 and which, in portions, is formed by a cutout 29a which extends in the region of the outer side of the socket element 31. However, the use of a socket element 31 is not mandatory.

FIG. 4C shows an illustration analogous to FIG. 4A, wherein the beam dump is formed by an insert opening 26 accommodating no carrier element 24, the insert opening being cylindrical in the example shown. In the mirror arrangement 22 depicted in FIG. 4C, the mount arrangement 25 is produced by additive manufacturing using the 3-D printing method. The channel device 29 which serves to guide the coolant 30 was already introduced, in the form of cavities, into the material of the mount arrangement 25 or its main body during the production of the mount arrangement 25. The provision of the socket element 31 or the cutout 29a can be dispensed with in the mirror arrangement 22 depicted in FIG. 4C. It is understood that a dummy carrier element 24′ as described in the context of FIG. 4B can also be used as a beam dump in the case of the mirror arrangement 22 shown in FIG. 4C.

As an alternative to the exemplary embodiment described in FIG. 4B, it is possible for the channel system 37′ of the dummy carrier element 24′ to not be closed but instead have an inlet 40 for the coolant 38 and an outlet 41 for the coolant 38, as depicted in FIGS. 5A-5B, which each show a detail of the mirror arrangement 22. In the examples shown in FIGS. 5A-5B, the channel system 37′ of the dummy carrier element 24′ is not in fluid connection with the channel device 29 of the mount arrangement 25 via the inlet 40 and the outlet 41.

In the example shown in FIG. 5A, the coolant 38 is supplied to the inlet 40, which is formed on a fixing portion 42 of the dummy carrier element 24′ which protrudes beyond the insert opening 26, via a supply line (not depicted here) from an external cooling device and discharged from the outlet 41 via a discharge line (not depicted here) and transported to the external cooling device. The outlet 41 is also formed on the fixing portion 42 of the dummy carrier element 24′ protruding beyond the insert opening 26.

In the example shown in FIG. 5B, a heatsink 43 having a channel system 29 of a similar form to the channel system 29 of the mount arrangement 25 is arranged adjacent to the mount arrangement 25, the channel system being designed to supply the coolant 38 to the inlet 40 of the dummy carrier element 24′ and discharge the coolant from the outlet 41 of the dummy carrier element 24′. Thermal deformations of the mount arrangement 25 can be reduced by guiding the coolant 38 in the additional heatsink 43. In the case shown in FIG. 5B, it is desirable to seal the inlet 40 and the outlet 41 with the aid of seals (not depicted here). A radial and/or axial sealing concept can be used to this end. In the case of a suitable design of the respective seals, for example in the style of a suitable adapter or the like, it may optionally be possible to exchange the dummy carrier element 24′ without needing to interrupt the transport of the coolant 38 for this purpose. For example, a fluid-tight connection between the inlet 40 and the outlet 41 and the channel device 29 of the heatsink 43 can be established when the dummy carrier element 24′ is fixed in the mount arrangement 25.

Unlike what is depicted in FIGS. 5A-5B, the inlet 40 and the outlet 41 of the channel system 37′ of the dummy carrier element 24′ may also be fluid-tightly connected to the channel device 29 of the mount arrangement 25. In this case, the inlet 40 and the outlet 41 are attached not to the fixing portion 42 of the dummy carrier element 24′ but, for example, laterally to the seat portion 33 of the dummy carrier element 24′, opposite to the inner side 26a of the insert opening 26. In this case, the socket element 31 shown in FIG. 4B is dispensed with. In this case, a supply opening of the channel device 29 of the mount arrangement 25 opens into a ring space formed between the dummy carrier element 24′ and the inner side 26a of the insert opening 26. In this case, the channel device 29 of the mount arrangement 25 also has a discharge opening for the coolant 38, which opens into a (further) ring space, into which the outlet 41 of the dummy carrier element 24′ opens. The ring spaces can be sealed with the aid of radial seals, for example in the form of O-rings or the like.

Alternatively, the inlet 40 and the outlet 41 of the channel device 37′ of the dummy carrier element 24′ may also be formed on the head region 34′ of the dummy carrier element 24′, to be precise with a lateral offset from the insert opening 26 on a side of the head region 34′ facing the end face of the mount arrangement 25. In this case, a supply opening and a discharge opening of the channel device 29 of the mount arrangement 25 open into a respective interspace, into which the inlet 40 and the outlet 41, respectively, of the channel system 37′ of the dummy carrier element 24′ open. In this case, the respective interspaces can be sealed from the surroundings by way of an axial seal arrangement.

What is claimed is:

1. A mirror arrangement, comprising:
a plurality of MEMS mirror modules, each MEMS mirror module comprising a plurality of mirror elements configured to reflect radiation;
a plurality of carrier elements, each carrier element carrying a respective mirror element;
a mount arrangement comprising insert openings,
wherein:
each mirror element is accommodated in a respective insert opening; and
to absorb radiation: i) an insert opening does not accommodate a carrier element; and/or ii) an insert opening accommodates a dummy carrier element which does not carry a mirror element.

2. The mirror arrangement of claim 1, wherein, to absorb radiation, an insert opening does not accommodate a carrier element.

3. The mirror arrangement of claim 2, wherein the opening not accommodating a carrier element comprises an inner wall supporting a radiation absorbing coating and/or a radiation absorbing surface structure.

4. The mirror arrangement of claim 2, wherein the opening not accommodating a carrier element is gas-tightly sealed.

5. The mirror arrangement of claim 2, wherein the opening not accommodating a carrier element is gas-tightly sealed at an end distant from the mirror elements.

6. The mirror arrangement of claim 2, wherein, to absorb radiation, an insert opening accommodates a dummy carrier element which does not carry a mirror element.

7. The mirror arrangement of claim 1, wherein, to absorb radiation, an insert opening accommodates a dummy carrier element which does not carry a mirror element.

8. The mirror arrangement of claim 7, wherein the dummy carrier element comprises a head region protruding beyond the insert opening accommodating the dummy carrier element in a direction of the mirror elements.

9. The mirror arrangement of claim 8, wherein at least the head region of the dummy carrier is solid.

10. The mirror arrangement of claim 8, wherein a closed channel system comprising a coolant is in the dummy carrier element.

11. The mirror arrangement of claim 7, wherein the dummy carrier element comprises an absorbent coating and/or an absorbent surface structure on a head region protruding beyond the insert opening accommodating the dummy carrier element.

12. The mirror arrangement of claim 11, wherein at least the head region of the dummy carrier is solid.

13. The mirror arrangement of claim 11, wherein a closed channel system comprising a coolant is in the dummy carrier element.

14. The mirror arrangement of claim 7, wherein the dummy carrier element comprises a channel system configured to guide guiding a coolant, and the channel system comprises an inlet for the coolant and an outlet for the coolant.

15. The mirror arrangement of claim 14, wherein the inlet and the outlet of the channel system are fluid-tightly connected to a channel device of the mount arrangement or to a channel device of a heatsink adjacent the mount arrangement.

16. The mirror arrangement of claim 1, further comprising a channel device configured to guide a coolant, wherein the channel device is in the mount arrangement in a region of: i) at least one insert opening not accommodating a carrier element; and/or ii) a seat portion of at least one dummy carrier element.

17. The mirror arrangement of claim 16, wherein:
an inner wall of an insert opening is defined by a socket element incorporated in the mount arrangement; and
at least portions of the channel device are defined by a cutout extending in a region of an outer side of the socket element.

18. The mirror arrangement of claim 1, wherein an inner wall of at least one insert opening is defined by a socket element incorporated in the mount arrangement.

19. The mirror arrangement of claim 1, wherein:
the plurality of mirror elements are in a grid arrangement;
an insert opening not accommodating a carrier element and/or an insert opening accommodating a dummy carrier element is disposed: i) at a lateral edge of the grid arrangement; or ii) between the mirror elements of the grid arrangement.

20. An apparatus, comprising:
an illumination system configured to illuminate an object,
wherein the illumination system comprises a first mirror arrangement according to claim 1, and the apparatus is a lithography apparatus.

21. The apparatus of claim 20, wherein:
the illumination system further comprises a second mirror arrangement;
the second mirror arrangement comprises a plurality of mirror elements;
the second mirror arrangement is upstream of the first mirror arrangement along a light path through the illumination system to the object; and
the plurality of mirror elements of the second mirror arrangement are configured to radiate radiation absorbed by an insert opening of the first mirror arrangement that does not accommodate a carrier element and/or by an insert opening of the first mirror arrangement that accommodates a dummy carrier element.
